(19) United States
(12) Patent Application Publication
(10) Pub. No.: US 2017/0243803 A1
(43) Pub. Date: Aug. 24, 2017

(54) THERMALLY ENHANCED SEMICONDUCTOR ASSEMBLY WITH THREE DIMENSIONAL INTEGRATION AND METHOD OF MAKING THE SAME

(71) Applicant: BRIDGE SEMICONDUCTOR CORPORATION, Taipei (TW)

(72) Inventors: Charles W. C. Lin, Singapore (SG); Chia-Chung Wang, Hsinchu County (TW)

(21) Appl. No.: 15/591,957

(22) Filed: May 10, 2017

Related U.S. Application Data
(63) Continuation-in-part of application No. 15/462,536, filed on Mar. 17, 2017.
Application No. 15/462,536 is a continuation-in-part of application No. 15/473,629, filed on Mar. 30, 2017.
Application No. 15/473,629 is a continuation-in-part of application No. 15/353,537, filed on Nov. 16, 2016.
Application No. 15/353,537 is a continuation-in-part of application No. 15/415,844, filed on Jan. 25, 2017.
Application No. 15/415,844 is a continuation-in-part of application No. 15/415,846, filed on Jan. 25, 2017.
Application No. 15/415,846 is a continuation-in-part of application No. 15/462,536, filed on Mar. 17, 2017.
Application No. 15/462,536 is a continuation-in-part of application No. 15/166,185, filed on May 26, 2016.
Application No. 15/166,185 is a continuation-in-part of application No. 15/289,126, filed on Oct. 8, 2016.
Application No. 15/353,537 is a continuation-in-part of application No. 15/166,185, filed on May 26, 2016.
Application No. 15/166,185 is a continuation-in-part of application No. 15/289,126, filed on Oct. 8, 2016.
Application No. 15/415,844 is a continuation-in-part of application No. 15/166,185, filed on May 26, 2016.
Application No. 15/166,185 is a continuation-in-part of application No. 15/289,126, filed on Oct. 8, 2016.
Application No. 15/289,126 is a continuation-in-part of application No. 15/353,537, filed on Nov. 16, 2016.
Application No. 15/415,846 is a continuation-in-part of application No. 15/166,185, filed on May 26, 2016.
Application No. 15/166,185 is a continuation-in-part of application No. 15/289,126, filed on Oct. 8, 2016.
Application No. 15/289,126 is a continuation-in-part of application No. 15/353,537, filed on Nov. 16, 2016.
Application No. 15/462,536 is a continuation-in-part of application No. 15/166,185, filed on May 26, 2016.
Application No. 15/166,185 is a continuation-in-part of application No. 15/289,126, filed on Oct. 8, 2016.
Application No. 15/289,126 is a continuation-in-part of application No. 15/353,537, filed on Nov. 16, 2016.
Application No. 15/289,126 is a continuation-in-part of application No. 15/166,185, filed on May 26, 2016.
(60) Provisional application No. 62/166,771, filed on May 27, 2015.

(51) Int. Cl. H01L 23/367; H01L 23/00; H01L 21/48; H01L 25/00; H01L 25/10; H01L 23/498

(52) U.S. Cl. CPC H01L 23/3675; H01L 25/105; H01L 23/49822; H01L 23/49833; H01L 21/4857; H01L 21/4882; H01L 21/481; H01L 21/4807; H01L 25/50; H01L 24/48; H01L 24/32; H01L 24/73; H01L 2225/1094; H01L 2225/1035; H01L 2225/1058; H01L 2224/48101; H01L 2224/48091; H01L 2224/48227; H01L 2224/73265; H01L 2224/32145

(57) ABSTRACT

A thermally enhanced semiconductor assembly with three dimensional integration includes a semiconductor chip electrically coupled to a wiring board by bonding wires. A heat spreader that provides an enhanced thermal characteristic for the semiconductor chip is disposed in a through opening of a wiring structure. Another wiring structure disposed on the heat spreader not only provides mechanical support, but also allows heat spreading and electrical grounding for the heat spreader by metallized vias. The bonding wires provide electrical connections between the semiconductor chip and the wiring board for interconnecting the semiconductor chip to terminal pads provided in the wiring board.

### CROSS REFERENCE TO RELATED APPLICATIONS

This application is a continuation-in-part of U.S. application Ser. No. 15/462,536 filed Mar. 17, 2017 and a continuation-in-part of U.S. application Ser. No. 15/473,629 filed Mar. 30, 2017. The U.S. application Ser. No. 15/462,536 is a continuation-in-part of U.S. application Ser. No. 15/166,185 filed May 26, 2016, continuation-in-part of U.S. application Ser. No. 15/289,126 filed Oct. 8, 2016 and continuation-in-part of U.S. application Ser. No. 15/353,537 filed Nov. 16, 2016. The U.S. application Ser. No. 15/473,629 is a continuation-in-part of U.S. application Ser. No. 15/166,185 filed May 26, 2016, continuation-in-part of U.S. application Ser. No. 15/289,126 filed Oct. 8, 2016, continuation-in-part of U.S. application Ser. No. 15/353,537 filed Nov. 16, 2016, a continuation-in-part of U.S. application Ser. No. 15/415,844 filed Jan. 25, 2017, a continuation-in-part of U.S. application Ser. No. 15/415,846 filed Jan. 25, 2017 and a continuation-in-part of U.S. application Ser. No. 15/462,536 filed Mar. 17, 2017. The U.S. application Ser. No. 15/166,185 claims the priority benefit of U.S. Provisional Application Ser. No. 62/166,771 filed May 27, 2015. The U.S. application Ser. No. 15/289,126 is a continuation-in-part of U.S. application Ser. No. 15/166,185 filed May 26, 2016. The U.S. application Ser. No. 15/353,537 is a continuation-in-part of U.S. application Ser. No. 15/166,185 filed May 26, 2016 and a continuation-in-part of U.S. application Ser. No. 15/289,126 filed Oct. 8, 2016. The U.S. application Ser. Nos. 15/415,844 and 15/415,846 are continuation-in-part of U.S. application Ser. No. 15/166,185 filed May 26, 2016, continuation-in-part of U.S. application Ser. No. 15/289,126 filed Oct. 8, 2016 and continuation-in-part of U.S. application Ser. No. 15/353,537 filed Nov. 16, 2016. The entirety of each of said Applications is incorporated herein by reference.

### FIELD OF THE INVENTION

The present invention relates to a semiconductor assembly and, more particularly, to a thermally enhanced semiconductor assembly with three dimensional integration in which a semiconductor chip is wire bonded to and thermally conductible to a wiring board having a heat spreader integrated with dual wiring structures, and a method of making the same.

### DESCRIPTION OF RELATED ART

Market trends of multimedia devices demand for faster and slimmer designs. However, as semiconductor devices are susceptible to performance degradation at high operational temperatures, assembling chips having stackable features for three-dimensional integration without proper heat dissipation measurements would worsen devices' thermal environment and may cause immediate failure during operation.

U.S. Pat. Nos. 8,132,320, 8,373,997, 8,400,776, 8,519,270, 8,530,751, 8,735,739, 8,850,701, 8,895,380, 8,942,003, 9,085,826, 9,159,713, 9,282,626, 9,340,003, 9,439,282 and 9,549,468 disclose various assembly structures having a cavity in the wiring board for slimmer or stackable considerations. However, as a dielectric layer is typically a thermally insulating material, circuitry disposed therein can only provide limited heat dissipation effect. Further, even if thermal vias are disposed in the board and underneath the cavity, the hot spot of a semiconductor chip may not be aligned with these thermal vias and render poor heat spreading efficiency.

Numerous attempts have been reported in the literature by inserting a metal or ceramic slug directly in the wiring board to compensate for this deficiency. However, this approach creates serious mechanical-related deficiencies. For example, wiring boards and their assemblies disclosed by U.S. Pat. Nos. 5,583,377, 6,861,750, 7,202,559, 7,462,933, 7,554,194, 7,919,853, 7,944,043, 7,968,371, 8,125,076, 8,188,379, 8,519,537, and 8,686,558 may render reliability and mechanical degradation problems. This is largely due to the heat sink disposed in the through opening is barely supported by the wiring board through flanges or adhesives, thermal expansion and shrinkage of the wiring board during operation would cause heat sink dislocation or distortion. Further, as the heat sink in the wiring board is often electrically and thermally isolated and its planar dimension is confined by the size of the through opening, the electrical and thermal performances of the assemblies are significantly limited.

For the reasons stated above, and for other reasons stated below, an urgent need exists to provide a three dimensional semiconductor assembly that can address high packaging density, high thermal dissipation and robust mechanical reliability requirements.

### SUMMARY OF THE INVENTION

The objective of the present invention is to provide a thermally enhanced semiconductor assembly in which one or more semiconductor chips can be electrically connected to a wiring board through a plurality of bonding wires and at least one chip is thermally conductible to a heat spreader provided in the wiring board. The heat spreader is disposed in a through opening of a wiring structure and mechanically supported by, electrically connected with, and thermally dissipated through another wiring structure, thereby improving mechanical, thermal and electrical performances of the assembly.

In accordance with the foregoing and other objectives, the present invention provides a thermally enhanced semiconductor assembly having a first semiconductor chip electrically connected to a wiring board through bonding wires. The wiring board includes a heat spreader, a first wiring structure and a second wiring structure. In a preferred embodiment, the first semiconductor chip is attached on and thermally conductible to the heat spreader; the first wiring structure laterally surrounds peripheral edges of the heat spreader and the first semiconductor chip, and is electrically coupled to the first semiconductor chip by bonding wires to provide fan-out routing; and the second wiring structure covers the first wiring structure and the heat spreader to provide mechanically support, and is thermally conductible to the heat spreader and electrically coupled to the first wiring structure.

Accordingly, the present invention provides a method of making a thermally enhanced semiconductor assembly with three dimensional integration, comprising: providing a wiring board, that includes (i) inserting a heat spreader into a through opening of a first wiring structure, with a backside surface of the heat spreader being substantially coplanar with a first surface of the first wiring structure, and (ii) forming a second wiring structure on the backside surface of the heat spreader and the first surface of the first wiring structure, wherein the second wiring structure is electrically coupled to the first wiring structure and thermally conductible to the heat spreader through metallized vias; disposing a first semiconductor chip in the through opening of the first wiring structure and over the heat spreader; and providing a plurality of bonding wires that electrically couple the first semiconductor chip to a second surface of the first wiring structure opposite to the first surface.

Unless specifically indicated or using the term “then” between steps, or steps necessarily occurring in a certain order, the sequence of the above-mentioned steps is not limited to that set forth above and may be changed or reordered according to desired design.

The semiconductor assembly and the method of making the same according to the present invention have numerous advantages. For instance, inserting the heat spreader in the through opening of the first wiring structure and forming the second wiring structure on the heat spreader and the first wiring structure is particularly advantageous as the heat spreader provided in the through opening of the first wiring structure can be mechanically supported by and thermally dissipated through the second wiring structure to enhance heat dissipation for the first semiconductor chip and mechanical reliability of the assembly. Inserting the first semiconductor chip into the through opening of the first wiring structure of the wiring board can provide mechanical housing for the first semiconductor chip and place the first semiconductor chip on the heat spreader for effective thermal dissipation. Additionally, attaching the bonding wires to the first semiconductor chip and the wiring board can offer a reliable channel for connecting the first semiconductor chip in a cavity of the wiring board to terminal pads provided in the wiring board.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIG. 1 is a cross-sectional view of a first wiring structure in accordance with the first embodiment of the present invention;

FIG. 2 is a cross-sectional view of the structure of FIG. 1 further provided with a heat spreader in accordance with the first embodiment of the present invention;

FIG. 3 is a cross-sectional view of the structure of FIG. 2 further provided with a second wiring structure to finish the fabrication of a wiring board in accordance with the first embodiment of the present invention;

FIG. 4 is a cross-sectional view of the structure of FIG. 3 further provided with a first semiconductor chip in accordance with the first embodiment of the present invention;

FIG. 5 is a cross-sectional view of the structure of FIG. 4 further provided with bonding wires to finish the fabrication of a semiconductor assembly in accordance with the first embodiment of the present invention;

FIG. 6 is a cross-sectional view of the structure of FIG. 5 further provided with an encapsulant in accordance with the first embodiment of the present invention;

FIG. 7 is a cross-sectional view of the structure of FIG. 6 further provided with a semiconductor device in accordance with the first embodiment of the present invention;

FIG. 8 is a cross-sectional view of the structure of FIG. 7 further provided with solder balls in accordance with the first embodiment of the present invention;

FIG. 9 is a cross-sectional view of the inverted structure of FIG. 6 further provided with a semiconductor device and solder balls in accordance with the first embodiment of the present invention;

FIG. 10 is a cross-sectional view of the inverted structure of FIG. 6 further provided with semiconductor devices, a heat spreader and solder balls in accordance with the first embodiment of the present invention;

FIG. 11 is a cross-sectional view of a wiring board in accordance with the second embodiment of the present invention;

FIG. 12 is a cross-sectional view of the structure of FIG. 11 further provided with a first semiconductor chip in accordance with the second embodiment of the present invention;

FIG. 13 is a cross-sectional view of the structure of FIG. 12 further provided with bonding wires to finish the fabrication of a semiconductor assembly in accordance with the second embodiment of the present invention;

FIG. 14 is a cross-sectional view of the structure of FIG. 13 further provided with an encapsulant in accordance with the second embodiment of the present invention;

FIG. 15 is a cross-sectional view of the inverted structure of FIG. 14 further provided with a semiconductor device and passive components in accordance with the second embodiment of the present invention;

FIG. 16 is a cross-sectional view of the structure of FIG. 15 further provided with an encapsulant and solder balls in accordance with the second embodiment of the present invention;

FIG. 17 is a cross-sectional view of another aspect of the semiconductor assembly in accordance with the second embodiment of the present invention;

FIG. 18 is a cross-sectional view of the structure with vertical connecting elements mounted on the structure of FIG. 5 in accordance with the third embodiment of the present invention;

FIG. 19 is a cross-sectional view of the structure of FIG. 18 further provided with an encapsulant to finish the fabrication of a semiconductor assembly in accordance with the third embodiment of the present invention;

FIG. 20 is a cross-sectional view of the structure of FIG. 19 further provided with a semiconductor device in accordance with the third embodiment of the present invention;

FIG. 21 is a cross-sectional view of the structure of FIG. 20 further provided with solder balls in accordance with the third embodiment of the present invention;

FIG. 22 is a cross-sectional view of another aspect of the semiconductor assembly in accordance with the third embodiment of the present invention;

FIG. 23 is a cross-sectional view of yet another aspect of the semiconductor assembly in accordance with the third embodiment of the present invention;

FIG. 24 is a cross-sectional view of a semiconductor assembly in accordance with the fourth embodiment of the present invention;

FIG. 25 is a cross-sectional view of the structure of FIG. 24 further provided with an encapsulant in accordance with the fourth embodiment of the present invention;

FIG. 26 is a cross-sectional view of the structure of FIG. 25 further provided with a semiconductor device in accordance with the fourth embodiment of the present invention;

FIG. 27 is a cross-sectional view of the inverted structure of FIG. 25 further provided with semiconductor devices, a heat spreader and solder balls in accordance with the fourth embodiment of the present invention;

FIG. 28 is a cross-sectional view of another aspect of the semiconductor assembly in accordance with the fourth embodiment of the present invention;

FIG. 29 is a cross-sectional view of the structure of FIG. 28 further provided with first and second semiconductor devices and passive components in accordance with the fourth embodiment of the present invention;

FIG. 30 is a cross-sectional view of the structure of FIG. 29 further provided with an encapsulant and solder balls in accordance with the fourth embodiment of the present invention;

FIG. 31 is a cross-sectional view of a semiconductor assembly in accordance with the fifth embodiment of the present invention;

FIG. 32 is a cross-sectional view of the structure of FIG. 31 further provided with a semiconductor device and solder balls in accordance with the fifth embodiment of the present invention;

FIG. 33 is a cross-sectional view of the structure of FIG. 31 further provided with a lens and solder balls in accordance with the fifth embodiment of the present invention;

FIG. 34 is a cross-sectional view of a semiconductor assembly in accordance with the sixth embodiment of the present invention;

FIG. 35 is a cross-sectional view of the structure of FIG. 34 further provided with a semiconductor device and solder balls in accordance with the sixth embodiment of the present invention; and

FIG. 36 is a cross-sectional view of the structure of FIG. 34 further provided with a lens and solder balls in accordance with the sixth embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

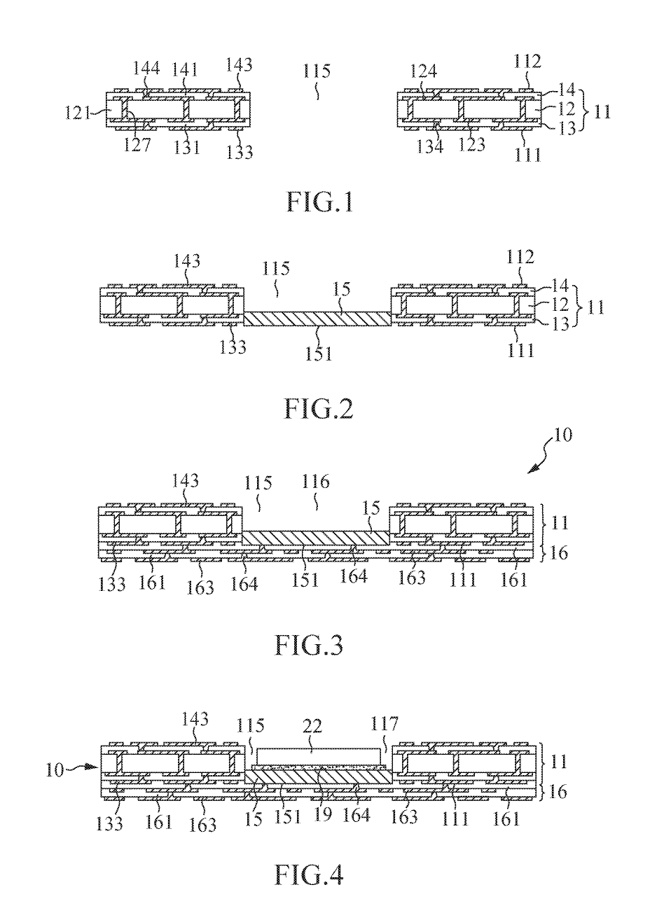

FIGS. 1-5 are schematic views showing a method of making a semiconductor assembly that includes a wiring board 10, a first semiconductor chip 22 and bonding wires 31 in accordance with the first embodiment of the present invention.

FIG. 1 is a cross-sectional view of a first wiring structure 11. The first wiring structure 11 has a through opening 115 extending from its first surface 111 to its second surface 112. In this illustration, the first wiring structure 11 includes an interconnect substrate 12, a first buildup circuitry 13 and a second buildup circuitry 14. The interconnect substrate 12 includes a core layer 121, a first routing layer 123, a second routing layer 124 and metallized through vias 127. The first routing layer 123 and the second routing layer 124 respectively extend laterally on both sides of the core layer 121, and metallized through vias 127 extend through the core layer 121 to provide electrical connections between the first routing layer 123 and the second routing layer 124. The first buildup circuitry 13 and the second buildup circuitry 14 are respectively disposed on both sides of the interconnect substrate 12, and each of them includes a dielectric layer 131, 141 and conductive traces 133, 143. The dielectric layers 131, 141 respectively cover both sides of the interconnect substrate 12 from below and above, and can be made of epoxy resin, glass-epoxy, polyimide, or the like. The conductive traces 133, 143 respectively extend laterally on the dielectric layers 131, 141, and include metallized vias 134, 144 in the dielectric layers 131, 141. The metallized vias 134, 144 contact the first and second routing layers 123, 124 of the interconnect substrate 12, and extend through the dielectric layers 131, 141.

FIG. 2 is a cross-sectional view of the structure with a heat spreader 15 disposed in the through opening 115 of the first wiring structure 11. The heat spreader 15 can be a thermally conductive layer made of, for example, metal, alloy, silicon, ceramic or graphite. In this embodiment, the heat spreader 15 is a metal layer and has a backside surface 151 substantially coplanar with the first surface 111 of the first wiring structure 11 from below.

FIG. 3 is a cross-sectional view of the structure with a second wiring structure 16 formed on the backside surface 151 of the heat spreader 15 and the first surface 111 of the first wiring structure 11. In this illustration, the second wiring structure 16 is a multi-layered buildup circuitry without a core layer, and includes multiple dielectric layers 161 and conductive traces 163 in an alternate fashion. The conductive traces 163 extend laterally on the dielectric layers 161 and include metallized vias 164 in the dielectric layers 161. Accordingly, the second wiring structure 16 can be electrically coupled to the first wiring structure 11 and the heat spreader 15 through the metallized vias 164 embedded in the dielectric layers 161 and in contact with the heat spreader 15 and the conductive traces 133 of the first wiring structure 11.

At this stage, a wiring board 10 is accomplished and includes a first wiring structure 11, a heat spreader 15 and a second wiring structure 16. As the depth of the through opening 115 is more than the thickness of the heat spreader 15, the exterior surface of the heat spreader 15 and the sidewall surface of the through opening 115 of the first wiring structure 11 forms a cavity 116 in the through opening 115 of the first wiring structure 11. As a result, the heat spreader 15 can provide thermal dissipation for a device accommodated in the cavity 116, whereas the combination of the first wiring structure 11 and the second wiring structure 16 offers electrical contacts for next connection from two opposite sides of the wiring board 10.

FIG. 4 is a cross-sectional view of the structure with a first semiconductor chip 22 attached to the wiring board 10. The semiconductor chip 22 is aligned with and disposed in the through opening 115 of the first wiring structure 11, with the first semiconductor chip 22 attached to the heat spreader 15 of the wiring board 10 using a thermally conductive material 19. The thermally conductive material 19 can be a solder (e.g., AuSn) or a silver/epoxy adhesive. The interior sidewalls of the through opening 115 laterally surround and are spaced from peripheral edges of the first semiconductor chip 22. As a result, a gap 117 is left in the through opening 115 between the peripheral edges of the first semiconductor chip 22 and the interior sidewalls of the first wiring structure 11. The gap 117 laterally surrounds the first semiconductor chip 22 and is laterally surrounded by the first wiring structure 11.

FIG. 5 is a cross-sectional view of the structure with bonding wires 31 attached to the wiring board 10 and the first semiconductor chip 22 typically by gold or copper ball bonding, or gold or aluminum wedge bonding. The bonding wires 31 contact and are electrically coupled to the first semiconductor chip 22 and the conductive traces 143 of the first wiring structure 11. As a result, the bonding wires 31 can electrically couple the first semiconductor chip 22 to the first wiring structure 11.

Accordingly, as shown in FIG. 5, a semiconductor assembly 110 is accomplished and includes a first semiconductor chip 22 electrically connected to a wiring board 10 by bonding wires 31. In this illustration, the wiring board 10 includes a first wiring structure 11, a heat spreader 15 and a second wiring structure 16.

The heat spreader 15 of the wiring board 10 is thermally conductible to and covers the first semiconductor chip 22 from below. The first wiring structure 11 laterally surrounds peripheral edges of the first semiconductor chip 22 and the heat spreader 15, and is electrically coupled to the first semiconductor chip 22 by the bonding wires 31. The second wiring structure 16 covers the first wiring structure 11 and the heat spreader 15 from below, and is electrically coupled to the first wiring structure 11 and thermally conductible to the heat spreader 15 through metallized vias 164. As a result, the first wiring structure 11 and the second wiring structure 16 can provide fan-out routing for the first semiconductor chip 22.

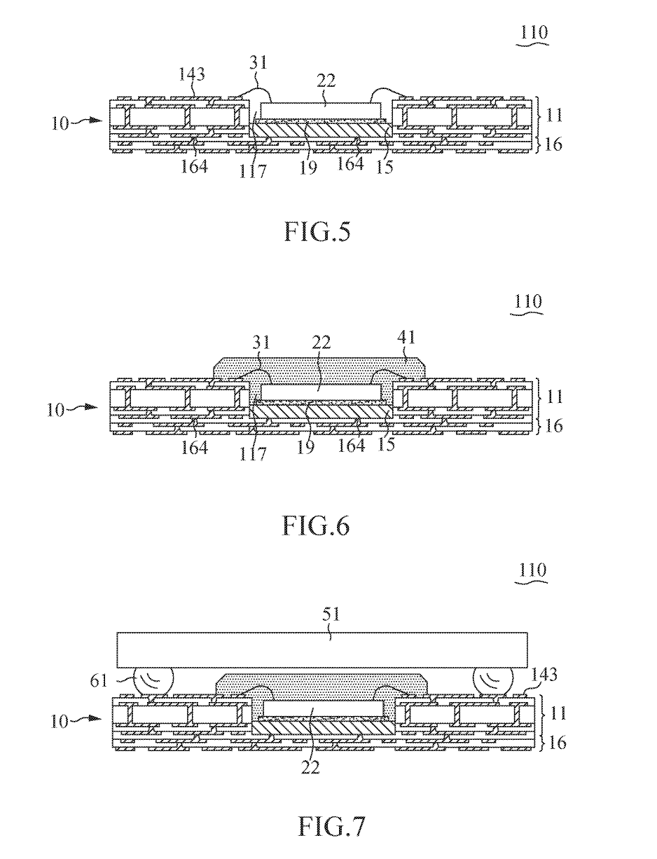

FIG. 6 is a cross-sectional view of the semiconductor assembly 110 of FIG. 5 further provided with an encapsulant 41. The encapsulant 41 covers the bonding wires 31 and the first semiconductor chip 22 as well as selected portions of the wiring board 10 from above, and further fills up the gap 117 between the peripheral edges of the first semiconductor chip 22 and the interior sidewalls of the wiring board 10.

FIG. 7 is a cross-sectional view of the semiconductor assembly 110 of FIG. 6 further provided with a semiconductor device 51 stacked over the first semiconductor chip 22 and the first wiring structure 11 of the wiring board 10. The semiconductor device 51 can be a ball grid array package or a bumped chip, and is electrically coupled to the conductive traces 143 of the first wiring structure 11 through solder balls 61.

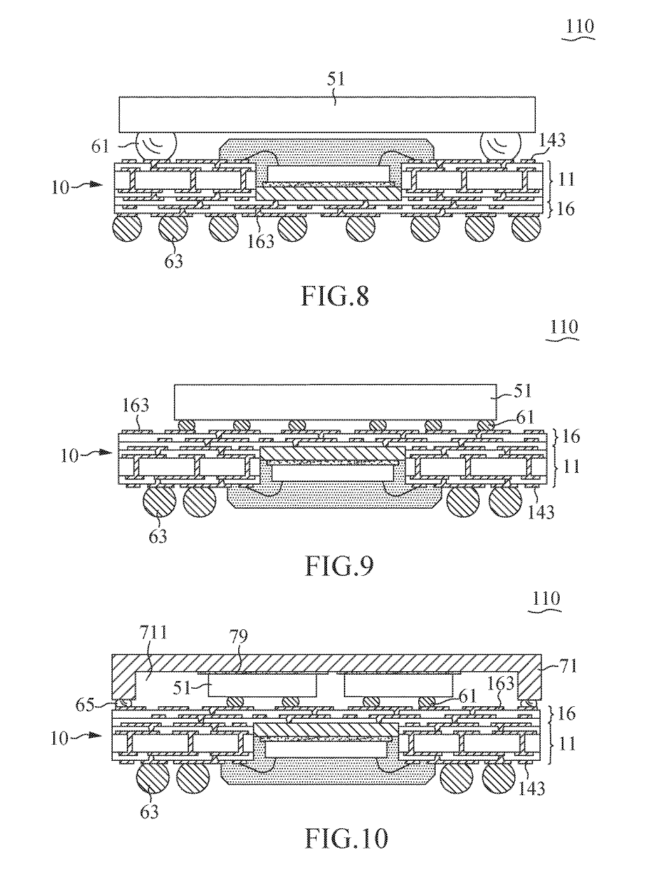

FIG. 8 is a cross-sectional view of the semiconductor assembly 110 of FIG. 7 further provided with solder balls 63. The solder balls 63 are mounted on the second wiring structure 16 of the wiring board 10 for external connection.

FIG. 9 is a cross-sectional view of the inverted semiconductor assembly 110 of FIG. 6 further provided with a semiconductor device 51 at the second wiring structure 16 and solder balls 63 at the first wiring structure 11. The semiconductor device 51 can be a ball grid array package or a bumped chip, and is electrically coupled to the conductive traces 163 of the second wiring structure 16 by solder balls 61. The solder balls 63 are mounted on the conductive traces 143 of the first wiring structure 11 for external connection.

FIG. 10 is a cross-sectional view of the inverted semiconductor assembly 110 of FIG. 6 further provided with semiconductor devices 51 and a heat spreader 71 at the second wiring structure 16 and solder balls 63 at the first wiring structure 11. The semiconductor devices 51 can be ball grid array packages or bumped chips accommodated in a cavity 711 of the heat spreader 71, and are electrically coupled to the conductive traces 163 of the second wiring structure 16 by solder balls 61. The heat spreader 71 is thermally conductive to the semiconductor devices 51 using a thermally conductive material 79, and electrically coupled to the conductive traces 163 of the second wiring structure 16 by solder balls 65. The solder balls 63 are mounted on the conductive traces 143 of the first wiring structure 11 for external connection.

### Embodiment 2

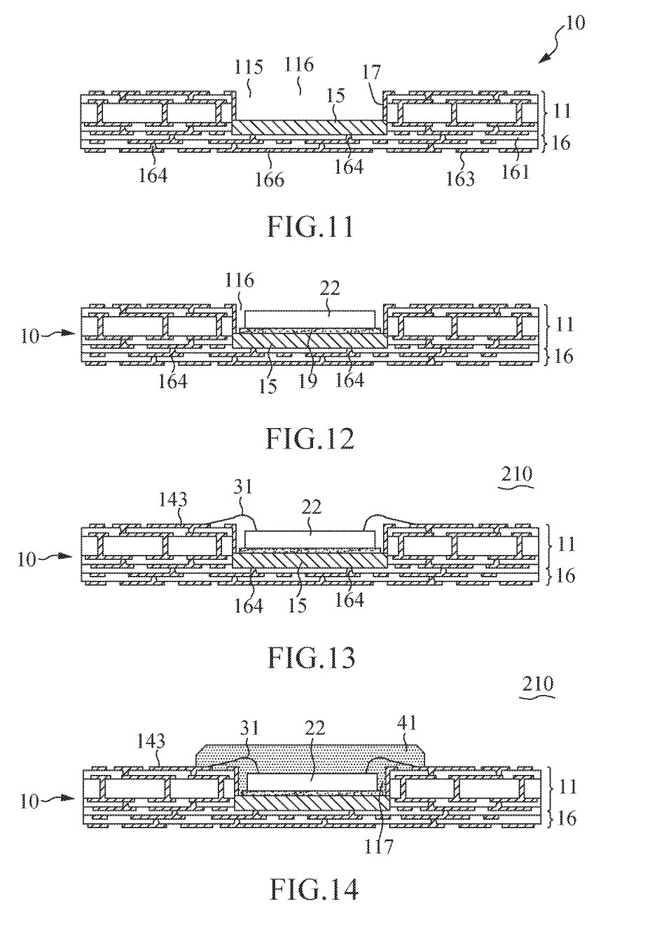

FIGS. 11-13 are schematic views showing a method of making a semiconductor assembly with the first semiconductor chip laterally surrounded by metallized sidewalls of the cavity of the wiring board in accordance with the second embodiment of the present invention.

For purposes of brevity, any description in Embodiment 1 above is incorporated herein insofar as the same is applicable, and the same description need not be repeated.

FIG. 11 is a cross-sectional view of a wiring board 10. The wiring board 10 is similar to that illustrated in FIG. 3, except that (i) a metal layer 17 is further formed on and completely covers sidewalls of the through opening 115 of the first wiring structure 11, and (ii) the outmost conductive traces 163 of the second wiring structure 16 includes a thermal pad 166. In this illustration, the exterior surface of the heat spreader 15 and the lateral surface of the metal layer 17 forms a cavity 116 in the through opening 115 of the first wiring structure 11.

FIG. 12 is a cross-sectional view of the structure with a first semiconductor chip 22 attached to the wiring board 10 of FIG. 11. The first semiconductor chip 22 is disposed in the cavity 116 of the wiring board 10 and attached to the heat spreader 15 using a thermally conductive material 19.

FIG. 13 is a cross-sectional view of the structure with bonding wires 31 attached to the first semiconductor chip 22 and the wiring board 10. The bonding wires 31 contact and are electrically coupled to the first semiconductor chip 22 and the conductive traces 143 of the first wiring structure 11.

Accordingly, as shown in FIG. 13, a semiconductor assembly 210 is accomplished and includes a first semiconductor chip 22 electrically connected to a wiring board 10 by bonding wires 31. In this illustration, the wiring board 10 includes a first wiring structure 11, a heat spreader 15, a second wiring structure 16 and a metal layer 17.

The heat spreader 15 covers the inactive surface of the first semiconductor chip 22 and is thermally conductible to the first semiconductor chip 22, whereas the metal layer 17 surrounds peripheral edges of the first semiconductor chip 22 and contacts the heat spreader 15. The first wiring structure 11 is electrically coupled to the first semiconductor chip 22 through bonding wires 31. The second wiring structure 16 covers the first wiring structure 11 and the heat spreader 15 from below, and is electrically coupled to the first wiring structure 11 for signal routing and to the heat spreader 15 for ground connection through metallized vias 164. Accordingly, the combination of the first wiring structure 11 and the second wiring structure 16 can provide fan-out routing for the first semiconductor chip 22 and electrical contacts for next-level connection, whereas the combination of the heat spreader 15 and the metal layer 17, electrically connected to the second wiring structure 16 through metallized vias 164, provides thermal dissipation and EMI (electromagnetic interference) shielding for the first semiconductor chip 22.

FIG. 14 is a cross-sectional view of the semiconductor assembly 210 of FIG. 13 further provided with an encapsulant 41. The encapsulant 41 covers the bonding wires 31, the first semiconductor chip 22 as well as selected portions of the first wiring structure 11 from above, and further fills up a gap 117 between the peripheral edges of the first semiconductor chip 22 and the interior sidewalls of the wiring board 10.

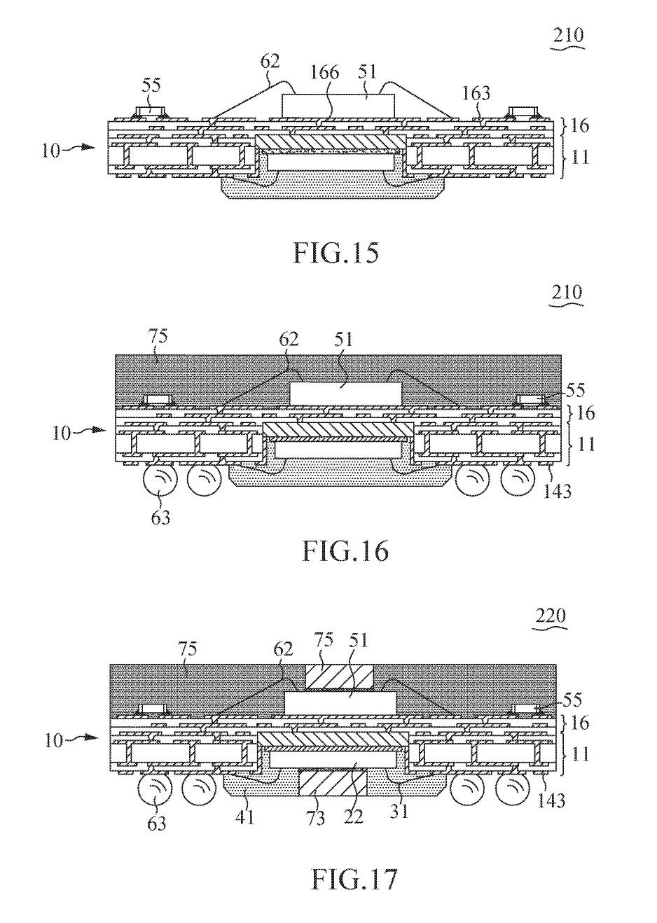

FIG. 15 is a cross-sectional view of the inverted semiconductor assembly 210 of FIG. 14 further provided with a semiconductor device 51 and passive components 55. The semiconductor device 51 is illustrated as a semiconductor chip, and is attached on the thermal pad 166 of the second wiring structure 16 and electrically coupled to the conductive traces 163 of the second wiring structure 16 by bonding wires 62. The passive components 55 are mounted on and electrically coupled to the conductive traces 163 of the second wiring structure 16.

FIG. 16 is a cross-sectional view of the semiconductor assembly 210 of FIG. 15 further provided with an encapsulant 75 and solder balls 63. The encapsulant 75 covers the bonding wires 62, the semiconductor device 51, the passive components 55 and the second wiring structure 16 from above. The solder balls 63 are mounted on the conductive traces 143 of the first wiring structure 11 for external connection.

FIG. 17 is a cross-sectional view of another aspect of the semiconductor assembly according to the second embodiment of the present invention. The semiconductor assembly 220 is similar to that illustrated in FIG. 16, except that it further includes heat spreaders 73, 75 attached to the first semiconductor chip 22 and the semiconductor device 51 and laterally covered by the encapsulants 41, 75, respectively.

### Embodiment 3

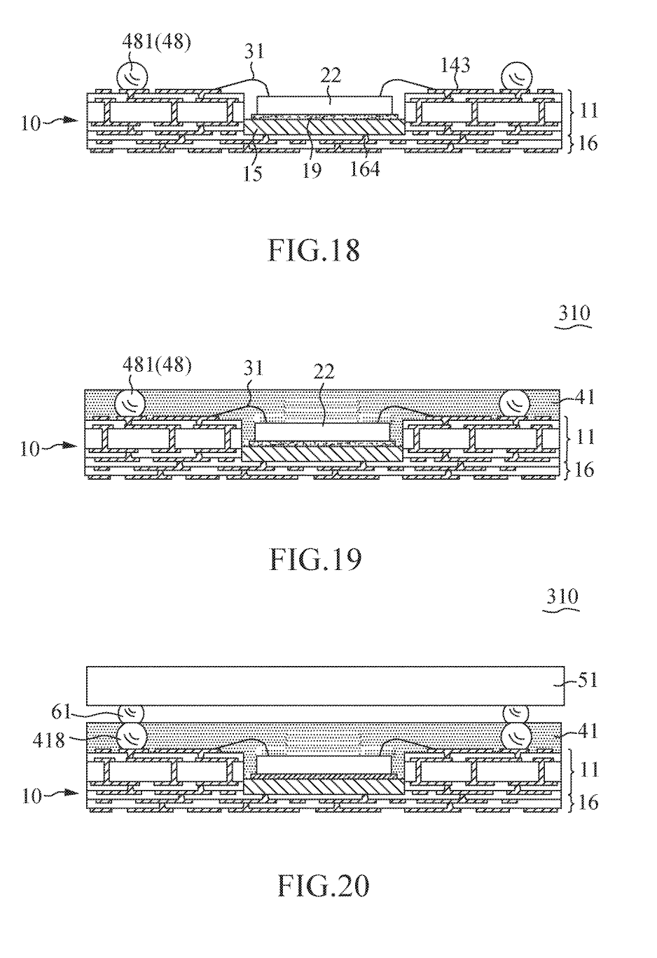

FIGS. 18-19 are schematic views showing a method of making a semiconductor assembly with vertical connecting elements on the wiring board in accordance with the third embodiment of the present invention.

For purposes of brevity, any description in Embodiments above is incorporated herein insofar as the same is applicable, and the same description need not be repeated.

FIG. 18 is a cross-sectional view of the structure with vertical connecting elements 48 mounted on the structure of FIG. 5. The vertical connecting elements 48 are electrically connected to and contact the conductive traces 143 of the first wiring structure 11. In this example, the vertical connecting elements 48 are illustrated as solder balls 481.

FIG. 19 is a cross-sectional view of the structure provided with an encapsulant 41. The encapsulant 41 covers sidewalls of the vertical connecting elements 48 and the bonding wires 31, the first semiconductor chip 22 and the wiring board 10 from above. Accordingly, a semiconductor assembly 310 is accomplished and includes a wiring board 10, a first semiconductor chip 22, bonding wires 31, an encapsulant 41 and vertical connecting elements 48. In this illustration, the wiring board 10 includes a first wiring structure 11, a heat spreader 15 and a second wiring structure 16.

FIG. 20 is a cross-sectional view of the semiconductor assembly 310 of FIG. 19 further provided with a semiconductor device 51. The semiconductor device 51 is stacked over the encapsulant 41, and electrically coupled to the vertical connecting elements 48 in the encapsulant 41 through solder balls 61.

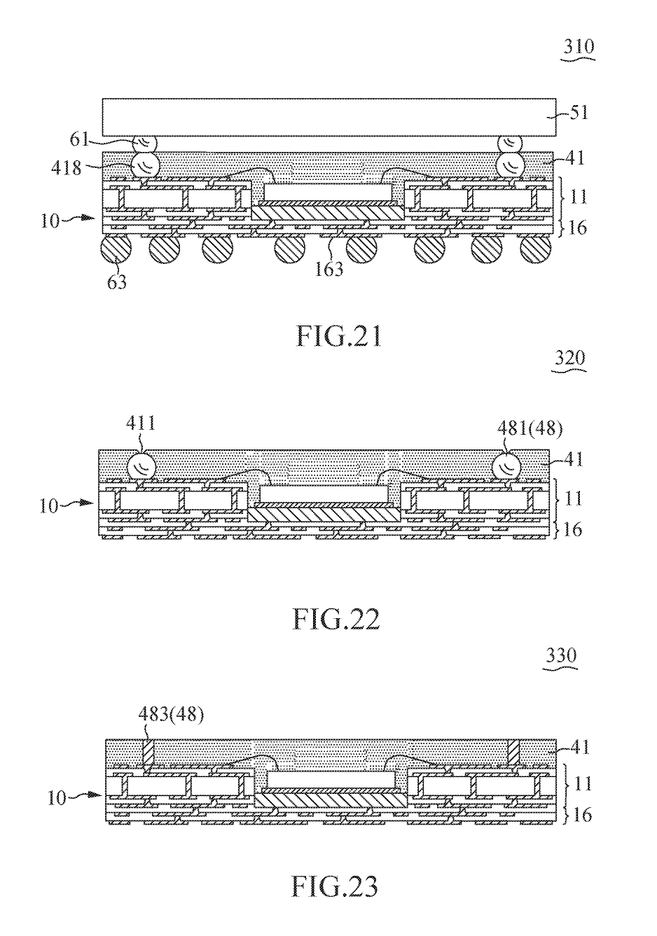

FIG. 21 is a cross-sectional view of the semiconductor assembly 310 of FIG. 20 further provided with solder balls 63. The solder balls 63 are mounted on the conductive traces 163 of the second wiring structure 16 for external connection.

FIG. 22 is a cross-sectional view of another aspect of the semiconductor assembly according to the third embodiment of the present invention. The semiconductor assembly 320 is similar to that illustrated in FIG. 19, except that the encapsulant 41 has a larger thickness than that of the solder balls 481, and has openings 411 to expose the solder balls 481 from above.

FIG. 23 is a cross-sectional view of yet another aspect of the semiconductor assembly according to the third embodiment of the present invention. The semiconductor assembly 330 is similar to that illustrated in FIG. 19, except that it includes metal posts 483 as the vertical connecting elements 48.

### Embodiment 4

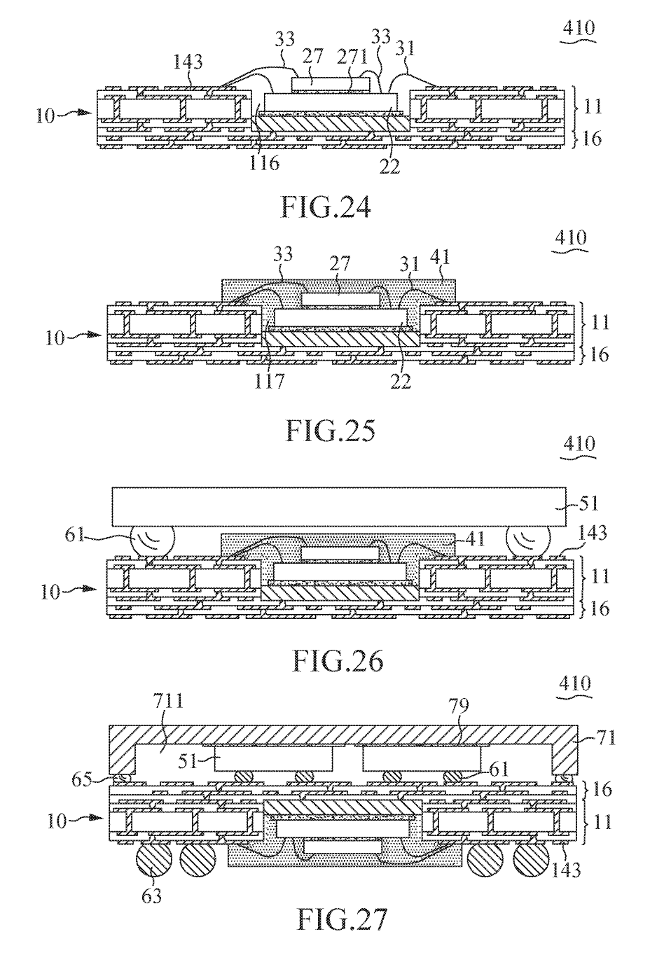

FIG. 24 is a cross-sectional view of a semiconductor assembly in accordance with the fourth embodiment of the present invention.

The semiconductor assembly 410 is similar to that illustrated in FIG. 5, except that it further includes a second semiconductor chip 27 stacked over he first semiconductor chip 22 by an adhesive 271 and electrically coupled to the first semiconductor chip 22 and the conductive traces 143 of the first wiring structure 11 by bonding wires 33.

FIG. 25 is a cross-sectional view of the semiconductor assembly 410 of FIG. 24 further provided with an encapsulant 41. The encapsulant 41 covers the bonding wires 31, 33, the first semiconductor chip 22 and the second semiconductor chip 27 as well as selected portions of the wiring board 10 from above, and further fills up a gap 117 between the peripheral edges of the first semiconductor chip 22 and the interior sidewalls of the wiring board 10.

FIG. 26 is a cross-sectional view of the semiconductor assembly 410 of FIG. 25 further provided with a semiconductor device 51 stacked over the encapsulant 41 and the first wiring structure 11 of the wiring board 10. The semiconductor device 51 is electrically coupled to the conductive traces 143 of the first wiring structure 11 through solder balls 61.

FIG. 27 is a cross-sectional view of the inverted semiconductor assembly 410 of FIG. 25 further provided with semiconductor devices 51 and a heat spreader 71 at the second wiring structure 16 and solder balls 63 at the first wiring structure 11. The semiconductor devices 51 are accommodated in a cavity 711 of the heat spreader 71, and electrically coupled to the second wiring structure 16 by solder balls 61. The heat spreader 71 is thermally conductive to the semiconductor devices 51 using a thermally conductive material 79, and electrically coupled to the second wiring structure 16 by solder balls 65. The solder balls 63 are mounted on the the first wiring structure 11 for external connection.

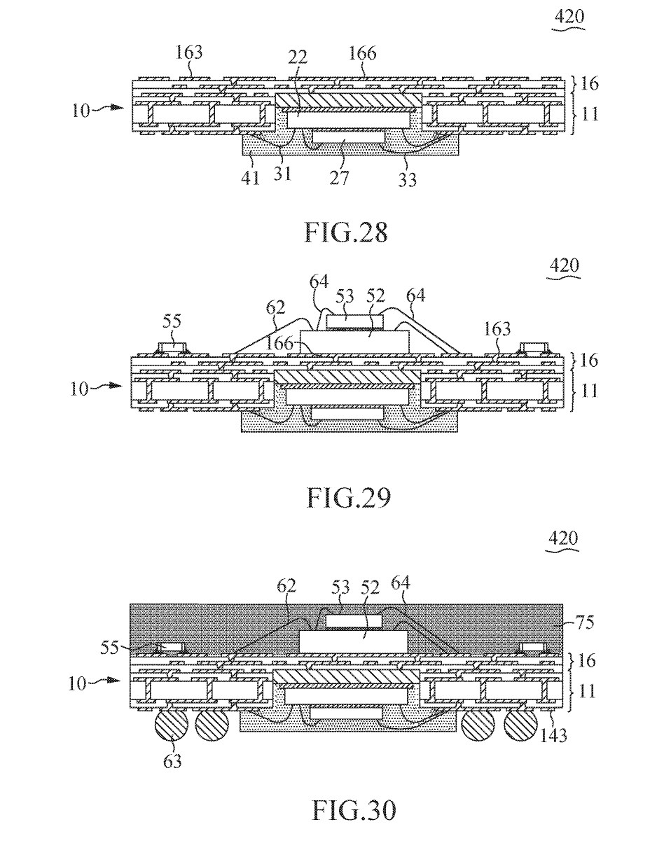

FIG. 28 is a cross-sectional view of another aspect of the semiconductor assembly according to the fourth embodiment of the present invention. The semiconductor assembly 420 is similar to the inverted structure illustrated in FIG. 25, except that the outmost conductive traces 163 of the second wiring structure 16 includes a thermal pad 166.

FIG. 29 is a cross-sectional view of the semiconductor assembly 420 of FIG. 28 further provided with a first semiconductor device 52, a second semiconductor device 53 and passive components 55. In this embodiment, the first semiconductor device 52 and the second semiconductor device 53 are illustrated as stacked semiconductor chips. The first semiconductor device 52 is mounted on the thermal pad 166 of the second wiring structure 16 and electrically coupled to the conductive traces 163 of the second wiring structure 16 by bonding wires 62. The second semiconductor device 53 is adhered to the first semiconductor device 52 and electrically coupled to the first semiconductor device 52 and the conductive traces 163 of the second wiring structure 16 by bonding wires 64. The passive components 55 are mounted on and electrically coupled to the conductive traces 163 of the second wiring structure 16.

FIG. 30 is a cross-sectional view of the semiconductor assembly 420 of FIG. 29 further provided with an encapsulant 75 and solder balls 63. The encapsulant 75 covers the bonding wires 62, 64, the first semiconductor device 52, the second semiconductor device 53, the passive components 55 and the second wiring structure 16 from above. The solder balls 63 are mounted on the conductive traces 143 of the first wiring structure 11 for external connection.

### Embodiment 5

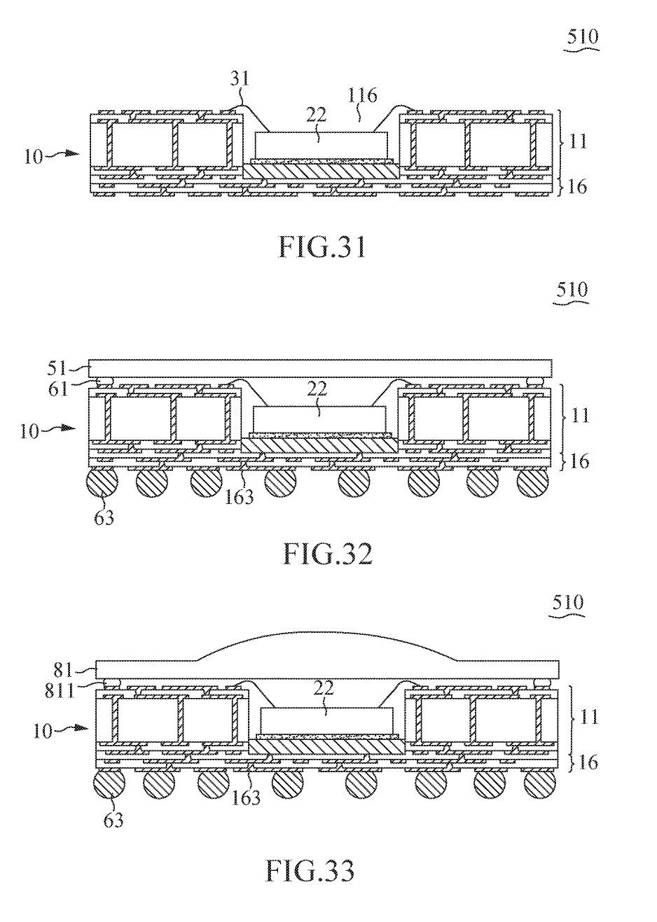

FIG. 31 is a cross-sectional view of a semiconductor assembly in accordance with the fifth embodiment of the present invention.

The semiconductor assembly 510 is similar to that illustrated in FIG. 5, except that the first wiring structure 11 of the wiring board 10 has a larger thickness to create a deeper cavity 116.

FIG. 32 is a cross-sectional view of the semiconductor assembly 510 of FIG. 31 further provided with a semiconductor device 51 at the first wiring structure 11 and solder balls 63 at the second wiring structure 16. The semiconductor device 51 is stacked over the wiring board 10 and the first semiconductor chip 22, and electrically coupled to the first wiring structure 11 through solder balls 61. The solder balls 63 are mounted on and electrically coupled to the second wiring structure 16 for external connection.

FIG. 33 is a cross-sectional view of the semiconductor assembly 510 of FIG. 31 further provided with a lens 81 at the first wiring structure 11 and solder balls 63 at the second wiring structure 16. The lens 81 optically transparent to at least one range of light wavelengths is mounted on the first wiring structure 11 using a joining material 811 and covers the first semiconductor chip 22 from above. The solder balls 63 are mounted on and electrically coupled to the second wiring structure 16 for external connection. The exemplary material of the lens 81 includes, but is not limited to, polycrystalline ceramics (e.g. aluminum oxide ceramics, aluminum oxynitride, perovskytes, polycrystalline yttrium aluminum garnet, etc.), single crystalline ceramics, non-crystalline materials (e.g. inorganic glasses and polymers), and glass ceramics (e.g. silicate based). The joining material 881 may be metal-based material (such as solder), epoxy-based material, polyimide, any other resin or appropriate material.

### Embodiment 6

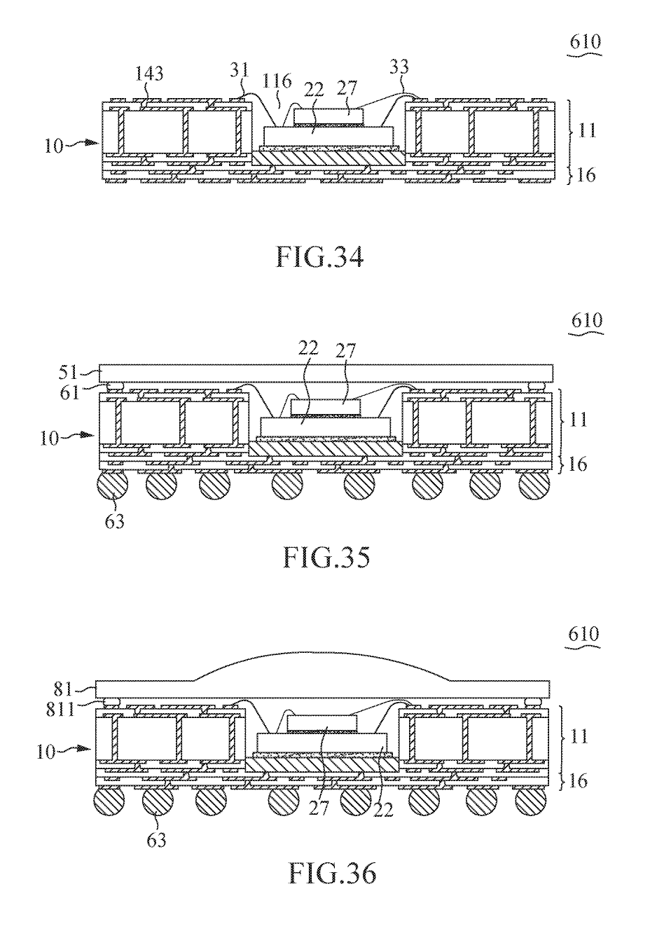

FIG. 34 is a cross-sectional view of a semiconductor assembly in accordance with the sixth embodiment of the present invention.

The semiconductor assembly 610 is similar to that illustrated in FIG. 24, except that the first wiring structure 11 of the wiring board 10 has a larger thickness to create a deeper cavity 116, and the second semiconductor chip 27 also extend into the cavity 116 of the wiring board 10.

FIG. 35 is a cross-sectional view of the semiconductor assembly 610 of FIG. 34 further provided with a semiconductor device 51 at the first wiring structure 11 and solder balls 63 at the second wiring structure 16. The semiconductor device 51 is stacked over the wiring board 10, the first semiconductor chip 22 and the second semiconductor chip 27, and electrically coupled to the first wiring structure 11 through solder balls 61. The solder balls 63 are mounted on and electrically coupled to the second wiring structure 16 for external connection.

FIG. 36 is a cross-sectional view of the semiconductor assembly 610 of FIG. 34 further provided with a lens 81 at the first wiring structure 11 and solder balls 63 at the second wiring structure 16. The lens 81 optically transparent to at least one range of light wavelengths is mounted to the first wiring structure 11 and covers the first semiconductor chip 22 and the second semiconductor chip 27 from above. The solder balls 63 are mounted on and electrically coupled to the second wiring structure 16 for external connection.

The semiconductor assemblies described above are merely exemplary. Numerous other embodiments are contemplated. In addition, the embodiments described above can be mixed-and-matched with one another and with other embodiments depending on design and reliability considerations. For instance, the first wiring structure may have multiple through openings in an array and each first semiconductor chip is accommodated in its corresponding through opening. Also, the first wiring structure of the wiring board can include additional conductive traces to receive and route additional first semiconductor chips.

For the convenience of below description, the direction in which the first surface of the first wiring structure faces is defined as the first direction, and the direction in which the second surface of the first wiring structure faces is defined as the second direction.

As illustrated in the aforementioned embodiments, a distinctive semiconductor assembly is configured by providing a first wiring structure, then inserting a heat spreader into a through opening of the first wiring structure, and then forming a second wiring structure on the heat spreader and the first wiring structure. Accordingly, the semiconductor assembly includes a first semiconductor chip electrically coupled to a wiring board by bonding wires. The wiring board includes a heat spreader, a first wiring structure and a second wiring structure. The first wiring structure includes electrical contacts at its second surface for chip connection and next-level connection from the second direction, whereas the second wiring structure includes electrical contacts at its exterior surface for next-level connection from the first direction. The heat spreader is laterally surrounded by the first wiring structure and covered by the second wiring structure from the first direction, and can provide a thermal dissipation pathway for the first semiconductor chip. Additionally, a second semiconductor chip may be stacked over first semiconductor chip by an adhesive and electrically coupled to the first wiring structure by a plurality of additional bonding wires. Optionally, an encapsulant may be further provided to cover the bonding wires.

The first wiring structure has a through opening extending from its first surface to its second surface to accommodate the heat spreader and the first semiconductor chip therein. The first wiring structure is not limited to a particular structure, and may be a multi-layered routing circuitry that laterally surround peripheral edges of the first semiconductor chip and the heat spreader. For instance, the first wiring structure may include an interconnect substrate, a first buildup circuitry and a second buildup circuitry. The first and second buildup circuitries are disposed on both opposite sides of the interconnect substrate. The interconnect substrate can include a core layer, first and second routing layers respectively on both opposite sides of the core layer, and metallized through vias formed through the core layer to provide electrical connection between the first and second routing layers. Each of the first and second buildup circuitries typically includes a dielectric layer and one or more conductive traces. The dielectric layers of the first and second buildup circuitries are respectively deposited on opposite sides of the interconnect substrate. The conductive traces extend laterally on the dielectric layer and include conductive vias in contact with first and second routing layers of the interconnect substrate. Further, the first and second buildup circuitries can include additional dielectric layers, additional via openings, and additional conductive traces if needed for further signal routing. Accordingly, the outmost conductive traces at both the first and second surfaces of the first wiring structure can provide electrical contacts for the chip connection and next-level connection from its second surface and for the second wiring structure connection from its first surface, and are electrically connected to each other.

The heat spreader is disposed in the through opening of the first wiring structure and has a thickness less than that of the first wiring structure so that a cavity is formed in the wiring board to accommodate the first semiconductor chip therein. Further, the heat spreader has peripheral edges adjacent to and attached to sidewalls of the through opening of the first wiring structure, and thus no electrical contacts are provided at the bottom of the cavity. In a preferred embodiment, the heat spreader is a metal layer that completely covers an inactive surface of the first semiconductor chip from the first direction to provide effective thermal dissipation and vertical EMI shielding for the first semiconductor chip attached thereto using a thermally conductive material. Further, the cavity may have metallic sidewalls by forming a metal layer that covers sidewalls of the through opening of the first wiring structure and is electrically coupled to the second wiring structure by the metallized vias in contact with the backside surface of the heat spreader. Preferably, the metal layer contacts sidewalls of the through opening of the first wiring structure, and completely covers sidewalls of the first semiconductor chip to provide effective lateral EMI shielding for the first semiconductor chip.

The second wiring structure may be a multi-layered routing circuitry and laterally extends to peripheral edges of the first wiring structure. Preferably, the second wiring structure is formed by direct build-up process on the first wiring structure and the heat spreader and electrically coupled to the heat spreader and the first wiring structure by metallized vias embedded in a dielectric layer of the second wiring structure and in contact with the backside surface of the heat spreader and the first surface of the first wiring structure. More specifically, the second wiring structure can be a multi-layered buildup circuitry without a core layer, and includes dielectric layers and conductive traces in repetition and alternate fashion. The innermost dielectric layer covers the backside surface of the heat spreader and the first surface of the first wiring structure. The conductive traces include metallized vias in the dielectric layer and extend laterally on the dielectric layer. Accordingly, the heat spreader, covered by the dielectric layer of the second wiring structure from the first direction, can be mechanically supported by the second wiring structure and electrically coupled to the second wiring structure by the metallized vias for ground connection.

The outmost conductive traces of the first and second wiring structures can respectively accommodate conductive joints, such as solder balls or bonding wires, for electrical communication and mechanical attachment with an assembly, an electronic device, an additional heat spreader or others. For instance, a semiconductor device may be a semiconductor chip and mounted over and electrically coupled to the second wiring structure through a plurality of bonding wires, or be a ball grid array package or a bumped chip and mounted over and electrically coupled to the first wiring structure or the second wiring structure through a plurality of solder balls. For the aspect of the semiconductor device being flip-chip mounted on the second wiring structure, an additional heat spreader may be mounted over the second wiring structure, and the semiconductor device can be disposed in a cavity of the additional heat spreader and thermally conductible to the additional heat spreader through a thermally conductive material. Further, the additional heat spreader may be electrically coupled to the second wiring structure for ground connection by, for example, solder balls in contact with the additional heat spreader and the outmost conductive traces of the second wiring structure. Additionally, when the first semiconductor chip or/and the optional second semiconductor chip is an optical chip, a lens optically transparent to at least one range of light wavelengths may be stacked over the first semiconductor chip and the optional second semiconductor chip, and mounted on the first wiring structure of the wiring board.

The bonding wires provide electrical connections between the first semiconductor chip and the first wiring structure and between the optional second semiconductor chip and the first wiring structure. In a preferred embodiment, the bonding wires contact and are attached to an active surface of the first/second semiconductor chip exposed from the through opening of the first wiring structure and the second surface of the first wiring structure. As a result, the first semiconductor chip and the optional second semiconductor chip can be electrically connected to the wiring board for external connection through the bonding wires.

Optionally, an array of vertical connecting elements may be further provided in electrical connection with the wiring board for next-level connection. Preferably, the vertical connecting elements contact and are electrically coupled to the first wiring structure from the second surface of the first wiring structure. The vertical connecting elements can include metal posts, solder balls or others, and may be laterally covered by an encapsulant. As the vertical connecting elements have a selected portion not covered by the encapsulant, a semiconductor device can be further provided to be electrically coupled to the vertical connecting elements.

The term “cover” refers to incomplete or complete coverage in a vertical and/or lateral direction. For instance, in a preferred embodiment, the heat spreader covers the first semiconductor chip in the first direction regardless of whether another element such as the thermally conductive material is between the first semiconductor chip and the heat spreader.

The phrases “attached to”, “attached on”, “mounted to” and “mounted on” includes contact and non-contact with a single or multiple element(s). For instance, in a preferred embodiment, the peripheral edges of the heat spreader are attached to the sidewalls of the through opening regardless of whether the peripheral edges of the heat spreader contact the sidewalls of the through opening or are separated from the sidewalls of the through opening by an adhesive.

The phrases “electrical connection”, “electrically connected” and “electrically coupled” refer to direct and indirect electrical connection. For instance, in a preferred embodiment, the bonding wires directly contact and are electrically connected to the first wiring structure, and the first semiconductor chip is spaced from and electrically connected to the first wiring structure by the bonding wires.

The “first direction” and “second direction” do not depend on the orientation of the semiconductor assembly, as will be readily apparent to those skilled in the art. For instance, the first surface of the first wiring structure faces the first direction and the second surface of the first wiring structure faces the second direction regardless of whether the semiconductor assembly is inverted. Thus, the first and second directions are opposite one another and orthogonal to the lateral directions. Furthermore, the first direction is the upward direction and the second direction is the downward direction when the outer surface of the second wiring structure faces in the upward direction, and the first direction is the downward direction and the second direction is the upward direction when the outer surface of the second wiring structure faces in the downward direction.

The semiconductor assembly according to the present invention has numerous advantages. For instance, as the first semiconductor chip is connected to the first wiring structure of the wiring board by bonding wires, not by direct build-up process, the simplified process steps result in lower manufacturing cost. The heat spreader can provide thermal dissipation, electromagnetic shielding and moisture barrier for the first semiconductor chip. The second wiring structure can provide mechanical support for the heat spreader and dissipate heat from the heat spreader. The semiconductor assembly made by this method is reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A method of making a thermally enhanced semiconductor assembly with three dimensional integration, comprising:
providing a wiring board, including:
inserting a heat spreader into a through opening of a first wiring structure, with a backside surface of the heat spreader being substantially coplanar with a first surface of the first wiring structure, and
forming a second wiring structure on the backside surface of the heat spreader and the first surface of the first wiring structure, wherein the second wiring structure is electrically coupled to the first wiring structure and thermally conductible to the heat spreader through metallized vias;
disposing a first semiconductor chip in the through opening of the first wiring structure and over the heat spreader; and
providing a plurality of bonding wires that electrically couple the first semiconductor chip to a second surface of the first wiring structure opposite to the first surface.

2. The method of claim 1, further comprising a step of providing a second semiconductor chip stacked over the first semiconductor chip by an adhesive and electrically coupled to the first wiring structure by a plurality of additional bonding wires.

3. The method of claim 1, further comprising a step of providing a semiconductor device stacked over and electrically coupled to the first wiring structure or the second wiring structure.

4. The method of claim 1, further comprising a step of stacking a lens over the first wiring structure, wherein the lens is optically transparent to at least one range of light wavelengths and covers the first semiconductor chip.

5. The method of claim 1, further comprising steps of:
providing an array of vertical connecting elements disposed on and electrically coupled to the first wiring structure; and
providing an encapsulant that covers the first semiconductor chip and the bonding wires and surrounds the vertical connecting elements.

6. The method of claim 5, further comprising a step of providing a semiconductor device stacked over the encapsulant and electrically coupled to the vertical connecting elements.

7. The method of claim 1, wherein the step of providing the wiring board further includes forming a metal layer that covers sidewalls of the through opening of the first wiring structure and contacts the heat spreader and is electrically coupled to the second wiring structure by the metallized vias in contact with the backside surface of the heat spreader.

8. The thermally enhanced semiconductor assembly with three dimensional integration, which is prepared by a method that comprises steps of:
providing a wiring board, including:
inserting a heat spreader into a through opening of a first wiring structure, with a backside surface of the heat spreader being substantially coplanar with a first surface of the first wiring structure, and
forming a second wiring structure on the backside surface of the heat spreader and the first surface of the first wiring structure, wherein the second wiring structure is electrically coupled to the first wiring structure and thermally conductible to the heat spreader through metallized vias;
disposing a first semiconductor chip in the through opening of the first wiring structure and over the heat spreader; and
providing a plurality of bonding wires that electrically couple the first semiconductor chip to a second surface of the first wiring structure opposite to the first surface.

9. The semiconductor assembly of claim 8, wherein the method further comprises a step of providing a second semiconductor chip stacked over the first semiconductor chip by an adhesive and electrically coupled to the first wiring structure by a plurality of additional bonding wires.

10. The semiconductor assembly of claim 8, wherein the method further comprises a step of providing a semiconductor device stacked over and electrically coupled to the first wiring structure or the second wiring structure.

11. The semiconductor assembly of claim 8, wherein the method further comprises a step of stacking a lens over the first wiring structure, wherein the lens is optically transparent to at least one range of light wavelengths and covers the first semiconductor chip.

12. The semiconductor assembly of claim 8, wherein the method further comprises steps of:
providing an array of vertical connecting elements disposed on and electrically coupled to the first wiring structure; and
providing an encapsulant that covers the first semiconductor chip and the bonding wires and surrounds the vertical connecting elements.

13. The semiconductor assembly of claim 12, wherein the method further comprises a step of providing a semiconductor device stacked over the encapsulant and electrically coupled to the vertical connecting elements.

14. The semiconductor assembly of claim 8, wherein the step of providing the wiring board further includes forming a metal layer that covers sidewalls of the through opening of the first wiring structure and contacts the heat spreader and is electrically coupled to the second wiring structure by the metallized vias in contact with the backside surface of the heat spreader.
